(19) United States
(12) Patent Application Publication
(10) Pub. No.: US 2011/0221465 A1
(43) Pub. Date: Sep. 15, 2011

(54) PROBE CARD AND MANUFACTURING METHOD THEREOF

(76) Inventor: Jae Ha Lee, Gyeonggi-do (KR)

(21) Appl. No.: 13/128,435

(22) PCT Filed: Oct. 23, 2009
(86) PCT No.: PCT/KR09/06173

§ 371 Date: May 10, 2011

(30) Foreign Application Priority Data
Nov. 21, 2008 (KR) 10-2008-0116261
Oct. 22, 2009 (KR) 10-2009-0100587

(51) Int. Cl. G01R 1/073; B32B 37/02; B32B 37/12; B32B 37/14; B32B 38/10

(52) U.S. Cl. 324/756.03; 156/250; 156/60

(57) ABSTRACT

A probe card and a manufacturing method thereof are provided. To manufacture the probe card, via holes for receiving probe pins are formed in a plate-shaped or block-shaped probe substrate, and the probe pins are simultaneously inserted into the via holes. Then the probe substrate is bonded onto a supportable board having a thermal expansion coefficient similar to that of a wafer, and the probe substrate is separated into individual parts each having a specific size that disallows a deviation in location of the probe pins from chip pads of the wafer in spite of thermal expansion of the probe substrate. Therefore, the probe card can be manufactured through a simpler and more cost-effective process while preventing a location deviation of the probe pins due to a difference in thermal expansion coefficient between the probe card and the wafer. The probe substrate and a main circuit board are electrically connected through connecting members passing through openings in the supportable board. The connecting members may be directly or indirectly connected to the main circuit board, and the probe substrate may be composed of first and second probe substrates.

### TECHNICAL FIELD

The present invention relates in general to a probe card and, more particularly, to a probe card having a plurality of probe pins used for a test of electrical properties of semiconductor chips in a wafer through a mechanical contact with the chips and also to a method for manufacturing the probe card.

### BACKGROUND ART

As well known in the art, after a large number of semiconductor chips are formed in and on a wafer through a wafer fabrication process, the wafer is separated into the individual chips and then a package assembly process is performed for each chip. An electrical die sorting (EDS) process is finally carried out in a wafer state before the package assembly process. Normally used to establish a connection between the semiconductor chips to be tested and test equipment is a probe card.

The semiconductor chip has a great number of input/output pads arranged on the surface thereof. In order to allow a mechanical contact with such pads and thereby form an electric signal path, the probe card has probe pins. The semiconductor chip receives a given signal from the test equipment through the probe pins, performs a particular operation depending on the signal, and outputs the operation result to the test equipment through the probe pins. Therefore, the test equipment can check electrical properties of the semiconductor chip and determine whether the semiconductor chip is good or bad.

Usually this test process is performed through a simultaneous contact between the probe pins and the chip pads for a fast and effective test. By the way, according as the semiconductor chip becomes smaller and the number of its pads increases, a distance between adjacent pads, namely, a pitch, is gradually reduced. The probe card is, therefore, required to have reduced-pitch probe pins that correspond to fine-pitch chip pads. However, it is very difficult to form reduced-pitch probe pins without causing electrical and mechanical interferences. Furthermore, to accurately arrange a large number of probe pins while keeping an excellent leveling is very critical but actually not easy. Additionally, a manufacturing method of the probe card should be simpler and cost-effective. Also, a pin contact failure caused by a difference in thermal expansion coefficient between a probe pin and a wafer should be favorably solved.

In view of the above reasons, the Applicant has continuously proposed various improvements in the probe card through Korean Patent No. 799166 (Method of Manufacturing Probe Array), Korean Patent No. 821674 (Probe Assembly), Korean Patent No. 858027 (Probe Assembly of Probe Card and Manufacturing Method Thereof), and Korean Patent Application No. 2008-0028824 (Probe Assembly of Probe Card and Manufacturing Method Thereof). This invention is another proposed improvement in the probe card.

### DISCLOSURE

### Technical Problem

As a wafer with a 300 mm diameter is widely used in these days, a large-sized probe card is also actively developed in the art. One of serious issues in such a large-sized probe card is a deviation in location of probe pins from chip pads due to a difference in thermal expansion coefficient between the probe card and the wafer. Another serious issue is to realize a simpler and more cost-effective method for manufacturing the probe card.

Accordingly, an aspect of the present invention is to prevent a deviation in location of probe pins from chip pads due to a difference in thermal expansion coefficient between a probe card and a wafer.

Another aspect of the present invention is to manufacture a probe card through a simpler and more cost-effective process.

Still another aspect of the present invention is to realize a simpler and more reliable electrical connection between a main circuit board and a probe substrate of a probe card.

### Technical Solution

In view of the above aspects, the present invention provides a technique to manufacture a probe card by forming via holes for receiving probe pins in a plate-shaped or block-shaped probe substrate, by simultaneously inserting the probe pins into the via holes through a method disclosed in Korean Patent Application No. 2008-0028824 to maintain a good arrangement of the probe pins, by bonding the probe substrate onto a supportable board having a thermal expansion coefficient similar to that of a wafer in order to complete a probe assembly with a good arrangement, and by separating the probe substrate into individual parts each having a specific size that disallows a deviation in location of probe pins from chip pads in spite of thermal expansion of the probe substrate.

According to one aspect of the present invention, provided is a probe card that comprises a main circuit board, a supportable board, a probe substrate, a conductive adhesive, and probe pins. The supportable board is combined with the main circuit board and is made of a material having a thermal expansion coefficient similar to that of a wafer. The probe substrate is bonded onto the supportable board, includes a circuit pattern formed therein and electrically connected to the main circuit board, and further includes a plurality of via holes electrically connected to the circuit pattern. The conductive adhesive is filled in the via holes. The probe pins are respectively inserted into the via holes, are mechanically fixed to the via holes through the conductive adhesive, and are electrically connected to the circuit pattern. Particularly, the probe substrate is separated into individual parts having a specific size that disallows a deviation in location of the probe pins from chip pads of the wafer in spite of thermal expansion or contraction of the probe substrate.

In the probe card, the probe substrate before being separated may have the shape of a circular plate resembling the wafer or be composed of a plurality of long blocks forming together a resultant shape resembling the wafer.

The probe card may further comprise connecting members that electrically connect the probe substrate and the main circuit board through at least one opening formed in the supportable board.

In the probe card, the main circuit board may include a through hole corresponding to the opening, and each of the connecting members may be connected at one end thereof to the probe substrate, pass through the opening and the through hole, and be connected at the other end thereof to a lower surface of the main circuit board.

In the probe card, the connecting members may be extended to a lower surface of the supportable board along a lateral side of the supportable board.

The probe card may further comprise second connecting members that electrically connect the main circuit board to the connecting members extended to the lower surface of the supportable board.

According to another aspect of the present invention, provided is a probe card that comprises a main circuit board, a supportable board, a first probe substrate, a second probe substrate, and probe pins. The supportable board is combined with the main circuit board and is made of a material having a thermal expansion coefficient similar to that of a wafer. The first probe substrate is bonded onto the supportable board, includes a circuit pattern formed therein and electrically connected to the main circuit board, and further includes a plurality of via holes electrically connected to the circuit pattern and filled with a conductive adhesive. The second probe substrate is bonded onto the first probe substrate, is made of a material having a thermal expansion coefficient similar to that of the wafer, includes first via holes formed at the same positions as the via holes of the first probe substrate, and further includes second via holes formed at positions different from the via holes of the first probe substrate and electrically connected to some of the first via holes. The probe pins are respectively inserted into the first via holes not connected to the second via holes and into the second via holes, are mechanically fixed to the inserted via holes through the conductive adhesive, and are electrically connected to the circuit pattern.

In the probe card, the first probe substrate may be separated into individual parts having a specific size that disallows mechanical deformation of the second probe substrate in spite of a difference in thermal expansion coefficient between the first and second probe substrates.

In the probe card, each of the first and second probe substrates may have the shape of a circular plate resembling the wafer or be composed of a plurality of long blocks forming together a resultant shape resembling the wafer.

The probe card may further comprise connecting members that electrically connect the first probe substrate and the main circuit board through at least one opening formed in the supportable board.

In the probe card, the main circuit board may include a through hole corresponding to the opening, and each of the connecting members may be connected at one end thereof to the first probe substrate, pass through the opening and the through hole, and be connected at the other end thereof to a lower surface of the main circuit board.

In the probe card, the connecting members may be extended to a lower surface of the supportable board along a lateral side of the supportable board.

The probe card may further comprise second connecting members that electrically connect the main circuit board to the connecting members extended to the lower surface of the supportable board.

According to still another aspect of the present invention, provided is a method for manufacturing a probe card, the method comprising steps of: preparing a supportable board made of a material having a thermal expansion coefficient similar to that of a wafer; preparing a probe substrate including a plurality of via holes filled with a conductive adhesive and electrically connected to a circuit pattern formed therein; inserting probe pins into the via holes of the probe substrate and then bonding the probe substrate onto the supportable board; separating the probe substrate into individual parts having a specific size that disallows a deviation in location of the probe pins from chip pads of the wafer in spite of thermal expansion or contraction of the probe substrate; and combining the supportable board with a main circuit board and then electrically connecting the probe substrate to the main circuit board.

In the method, the step of bonding the probe substrate onto the supportable board may use the probe substrate having the shape of a circular plate resembling the wafer or the probe substrate composed of a plurality of long blocks forming together a resultant shape resembling the wafer.

In the method, the step of inserting the probe pins into the via holes of the probe substrate may include simultaneously inserting the probe pins using a pin array frame.

In the method, the step of inserting the probe pins may be performed before or after the step of bonding the probe substrate onto the supportable board.

In the method, the supportable board may include at least one opening, and the step of electrically connecting the probe substrate to the main circuit board may use connecting members passing through the opening.

In the method, the main circuit board may include a through hole corresponding to the opening, and each of the connecting members may be connected at one end thereof to the probe substrate, pass through the opening and the through hole, and be connected at the other end thereof to a lower surface of the main circuit board.

In the method, the connecting members may be extended to a lower surface of the supportable board along a lateral side of the supportable board and electrically connected to the main circuit board through second connecting members.

According to yet another aspect of the present invention, provided is a method for manufacturing a probe card, the method comprising steps of: preparing a supportable board made of a material having a thermal expansion coefficient similar to that of a wafer; preparing a first probe substrate including a plurality of via holes filled with a conductive adhesive and electrically connected to a circuit pattern formed therein; preparing a second probe substrate made of a material having a thermal expansion coefficient similar to that of the wafer, including first via holes formed at the same positions as the via holes of the first probe substrate and filled with the conductive adhesive, and further including second via holes formed at positions different from the via holes of the first probe substrate, electrically connected to some of the first via holes, and filled with the conductive adhesive; inserting probe pins into the first via holes not connected to the second via holes and into the second via holes and then bonding the supportable board, the first probe substrate and the second probe substrate; and combining the supportable board with a main circuit board and then electrically connecting the first probe substrate to the main circuit board.

The method may further comprise a step of separating the first probe substrate into individual parts having a specific size that disallows mechanical deformation of the second probe substrate in spite of a difference in thermal expansion coefficient between the first and second probe substrates.

In the method, the step of bonding the supportable board, the first probe substrate and the second probe substrate may use the first and second probe substrates each having the shape of a circular plate resembling the wafer or composed of a plurality of long blocks forming together a resultant shape resembling the wafer.

In the method, the step of inserting the probe pins into the first and second via holes of the second probe substrate may include simultaneously inserting the probe pins using a pin array frame.

In the method, the step of inserting the probe pins may be performed before or after the step of bonding the supportable board and the first and second probe substrates.

In the method, the supportable board may include at least one opening, and the step of electrically connecting the first probe substrate to the main circuit board may use connecting members passing through the opening.

In the method, the main circuit board may include a through hole corresponding to the opening, and each of the connecting members may be connected at one end thereof to the first probe substrate, pass through the opening and the through hole, and be connected at the other end thereof to a lower surface of the main circuit board.

In the method, the connecting members may be extended to a lower surface of the supportable board along a lateral side of the supportable board and electrically connected to the main circuit board through second connecting members.

### Advantageous Effects

According to aspects of the present invention, the probe substrate is separated into individual parts each having a specific size that disallows a deviation in location of probe pins from chip pads in spite of thermal expansion of the probe substrate due to a difference in thermal expansion coefficient between the probe card and the wafer.

Additionally, by separately using both the second probe substrate for receiving the probes pins and the first probe substrate having a circuit pattern, and by forming the second probe substrate with a material having a thermal expansion coefficient similar to that of the wafer, aspects of this invention may prevent a deviation in location of probe pins from chip pads due to a difference in thermal expansion coefficient between the probe card and the wafer.

Furthermore, by bonding the probe substrate, having the shape of a circular plate resembling the wafer or composed of a plurality of long blocks forming together a resultant shape resembling the wafer, onto the supportable board, and then by separating the probe substrate into individual parts, aspects of this invention may manufacture the probe card through a simpler and more cost-effective process.

Moreover, by simultaneously inserting the probe pins into via holes of the probe substrate using a pin array frame, aspects of this invention may simplify a manufacturing process and also keep an excellent leveling of arranged probe pins.

Besides, aspects of this invention may realize a simpler and more reliable electrical connection between the main circuit board and the probe substrate by using the connecting members, openings in the supportable board, and through holes of the main circuit board.

### DESCRIPTION OF DRAWINGS

FIG. 1 is a perspective view partially showing a probe card in accordance with the first embodiment of the present invention.

FIG. 2 is a cross-sectional view taken along an X axis of FIG. 1.

FIGS. 3 to 6 are views showing a method for manufacturing the probe card in accordance with the first embodiment of the present invention wherein FIG. 3 is a plan view of a supportable board; FIG. 4 is a plan view of a probe substrate; FIG. 5 is a plan view showing the supportable board and the probe substrate after a bonding step; and FIG. 6 is a plan view showing the supportable board and the probe substrate after a chip-size separation step.

FIG. 7 is a plan view showing a modification of a probe substrate.

FIG. 8 is a cross-sectional view partially showing a probe card in accordance with the second embodiment of the present invention.

FIG. 9 is a cross-sectional view partially showing a probe card in accordance with the third embodiment of the present invention.

FIG. 10 is a cross-sectional view partially showing a probe card in accordance with the fourth embodiment of the present invention.

FIG. 11 is a cross-sectional view showing the probe card in accordance with the fourth embodiment of the present invention.

### BEST MODE

Exemplary, non-limiting embodiments of the present invention will now be described more fully with reference to the accompanying drawings. This invention may, however, be embodied in many different forms and should not be construed as limited to the exemplary embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

Furthermore, well known or widely used techniques, elements, structures, and processes may not be described or illustrated in detail to avoid obscuring the essence of the present invention. Although the drawings represent exemplary embodiments of the invention, the drawings are not necessarily to scale and certain features may be exaggerated or omitted in order to better illustrate and explain the present invention. Like reference numerals in the drawings denote like elements.

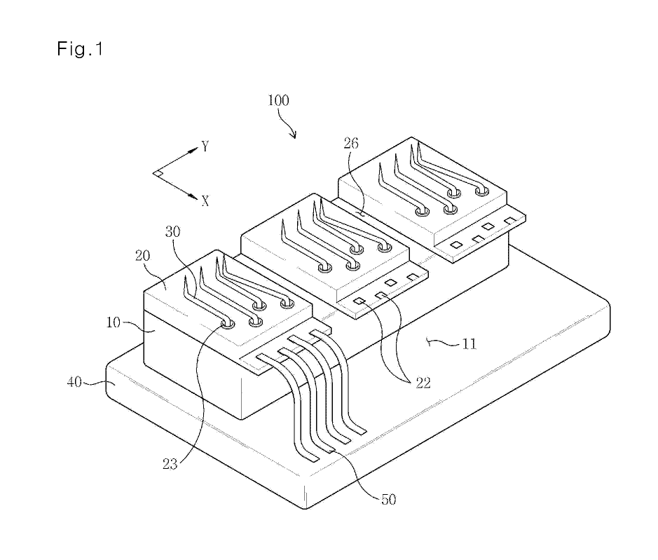

FIG. 1 is a perspective view partially showing a probe card in accordance with the first embodiment of the present invention.

Referring to FIG. 1, the probe card 100 includes a supportable board 10, a probe substrate 20, probe pins 30, a main circuit board 40, and connecting members 50. The supportable board 10 is formed of a material having a thermal expansion coefficient similar to that of a wafer. The probe substrate 20 has a circuit pattern formed therein and receives the probe pins 30 inserted therein and mounted thereon. The probe substrate 20 is bonded in the form of a plate or long block onto the supportable board 10 and then separated into individual ones each having a given size.

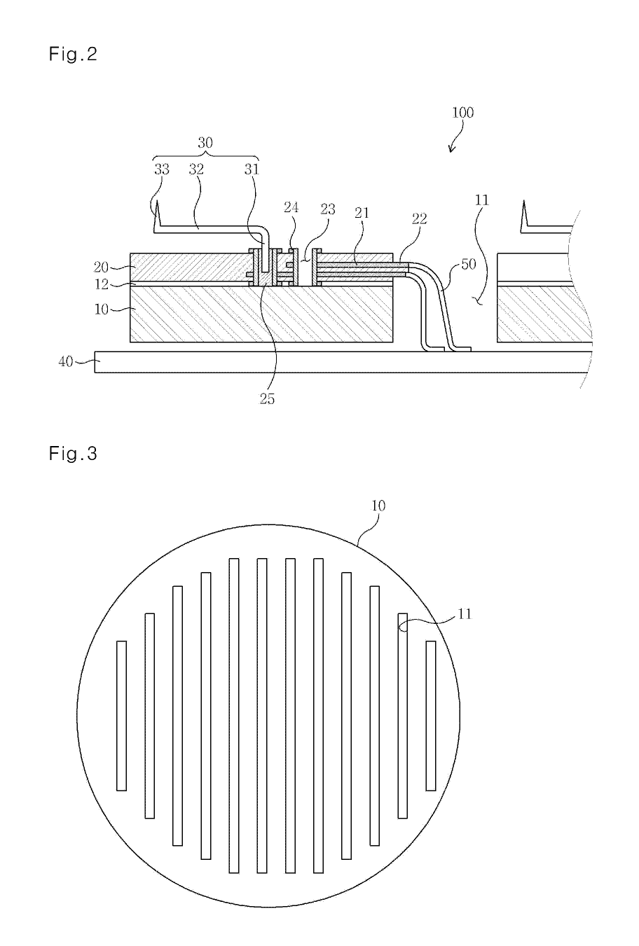

FIG. 2 is a cross-sectional view taken along an X axis of FIG. 1. Hereinafter, the configuration of the probe card 100 will be described in more detail with reference to FIGS. 1 and 2.

The supportable board 10 is a circular plate like a wafer and is made of a material, such as silicon, ceramic, glass, etc., having a thermal expansion coefficient similar to that of the wafer. The supportable board 10 is interposed between the main circuit board 40 and the probe substrate 20 so as to offer a mechanical base for supporting the probe substrate 20 and has no circuit pattern. The supportable board 10 may have a circular shape like a wafer or alternatively be composed of a plurality of long blocks which form together a resultant shape resembling the wafer. As will be described again later, a plurality of openings 11 are formed in the supportable board 10 at regular intervals, and the connecting members 50 pass through the openings 11 so as to electrically connect the probe substrate 20 to the main circuit board 40. Additionally, the supportable board 10 may act as a typical stiffener attached to the bottom of the main circuit board 40.

The probe substrate 20 is a rigid flexible printed circuit board (RFPCB), composed of one of a PCB, a flexible PCB (FPCB) and a ceramic board or a combination thereof, having a circuit pattern 21 formed therein and a plurality of pads 22 (which are not identical to typical pads of a semiconductor chip) formed on a peripheral region of the surface thereof. The circuit pattern 21 is electrically connected to the pads 22 and may be formed in multiple layers. The pads 22 are arranged with fine pitches along one edge of the surface of the probe substrate 20. As will be described again later, the pads 22 are electrically connected to the main circuit board 40 through the connecting members 50. Like the supportable board 10, the probe substrate 20 may have a circular shape resembling a wafer or alternatively be composed of a plurality of long blocks. The probe substrate 20 is bonded onto the supportable board 10 and then separated into individual ones in the direction of the Y axis of FIG. 1. A reference numeral 26 indicates a separation region of the probe substrate 20, which will be described again later. A bonding between the probe substrate 20 and the supportable board 10 may be made through a nonconductive adhesive 12 such as epoxy.

Additionally, the probe substrate 20 has a plurality of via holes 23. Each via hole 23 vertically penetrates the probe substrate 20 and has a plated layer 24 formed on the inner wall thereof so as to establish an electrical connection with the circuit pattern 21. The completely penetrated via-hole 23 in the probe substrate 20 makes it easy to form the plated layer 24 on the inner wall in comparison with a non-completely penetrated via-hole. The via holes 23 are filled with a conductive adhesive 25 having electrical conductivity. For example, the conductive adhesive 25 is a liquid adhesive containing metal powder, solder paste, molten solder, or the like. Although FIG. 2 shows the conductive adhesive 25 and the probe pin 30 formed only in the left via hole 23 and omits those from the right via hole 23, this is merely to avoid the complexity of drawings.

Each probe pin 30 may have a cantilever form, as shown in FIGS. 1 and 2. However, the probe pin 30 is not limited to such a shape and may alternatively have any shape that allows the probe pin to elastically press the chip pad on a wafer and to be restored to the original state when the probe pin is separated from the chip pad. The probe pin 30 is formed of tungsten (W), rhenium tungsten (ReW), beryllium copper (BeCu), nickel (Ni) alloy that is a MEMS (Micro Electro-Mechanical System) material, or any other conductive materials.

In case where the probe pin 30 has a cantilever form, the probe pin 30 is composed of a connecting post 31, a horizontal beam 32 and a contact tip 33, which are integrated with each other. The connecting post 31 of the probe pin 30 is inserted into the via hole 23 of the probe substrate 20 in the vertical direction, is mechanically fixed to the via hole 23 through the conductive adhesive 25, and is electrically connected to the circuit pattern 21 of the probe substrate 20. The horizontal beam 32 is extended from the connecting post 31 in the horizontal direction and separated from the surface of the probe substrate 20. The contact tip 33 is extended from the horizontal beam 32 in a direction opposite to the connecting post 31 at a location opposite to the connecting post 31. The contact tip 33 is a part to mechanically come into contact with the chip pad. Alternatively, the probe pin 30 may have an almost vertical shape having no horizontal beam.

The main circuit board 40 is a normal probe card circuit board. The main circuit board 40 is combined with the supportable board 10, and pads (not shown) of the main circuit board 40 are electrically connected to the pads 22 of the probe substrate 20 through the connecting members 50. Although not illustrated in drawings, the main circuit board 40 and the supportable board 10 may be combined with each other using a screw, a nonconductive adhesive, or the like. In any case, a certain additional stiffener may be attached to the lower surface of the main circuit board 40 when the main circuit board 40 is combined with the supportable board 10. However, since the supportable board 10 serves as the stiffener as described above, no additional stiffener is normally required. In another embodiment, the main circuit board 40 may have any through holes corresponding to the openings 11 of the supportable board 10, and the connecting members 50 may be connected to the lower surface of the main circuit board 40 through the through holes of the main circuit board 40. This will be described again later.

The connecting members 50 may use a gold wire used in a typical wire bonding technology, a cable wire, an FPCB cable, or the like. Alternatively, the circuit pattern 21 of the probe substrate 20 may be extended and used to substitute for the connecting members 50. In case where the probe substrate 20 is an FPCB, the probe substrate 20 can act as the connecting members 50. The connecting members 50 shown in FIG. 1 are respectively connected to the pads 22. Alternatively, the connecting members 50 may have an integrated form like a normal FPCB and be simultaneously bonded to the pads 22. Also, the circuit pattern 21 in the probe substrate 20 may be extended outwardly and acts as the connecting members 50 in the form of a normal FPCB. And also, as shown in FIG. 2, the connecting members 50 may be respectively connected to the multi-level circuit patterns 21. In another embodiment, the connecting members 50 may have an integrated form in which microstrips or striplines are organized by the multi-level circuit patterns 21 with insulating layers interposed.

In the above-discussed probe card 100, the supportable board 10 has a thermal expansion coefficient similar to that of the wafer. However, due to the circuit pattern 21, the probe substrate 20 on which the probe pins 30 are mounted has a thermal expansion coefficient greater (e.g., twice to five times according to the material of the probe substrate) than that of the wafer. Therefore, in a test process requiring a thermal variation such as a hot test (120° C.) or a cold test (−40° C.), the probe substrate 20 is thermally expanded or contracted much more than the wafer. Unfortunately, this may cause the above-discussed problem that the probe pins 30 on the probe substrate 20 deviate the chip pad on the wafer.

This problem is favorably solved by separating the probe substrate 20 into individual ones each having a given size and thus creating gaps between the separated probe substrates 20. Therefore, even though the thermal expansion coefficient of the probe substrate 20 is higher than that of the wafer, a variation in geometrical size of the probe substrate 20 due to thermal expansion becomes smaller. Specifically, if the probe substrate 20 is separated into individual parts at an interval of 1 cm, the thermal expansion of the wafer is 3.84 μm (3.2×0.01 m×120° C.) and the thermal expansion of the probe substrate is 13.2 μm (11×0.01 m×120° C.) at a test temperature of 120° C. Namely, a difference in thermal expansion between the probe substrate and the wafer is merely 9.36 μm. Therefore, the probe pin do not deviate from the chip pad normally having a size of about 70 μm.

Now, a method for manufacturing a probe card according to the present invention will be described. The structure of the probe card will be much clearer from the following description.

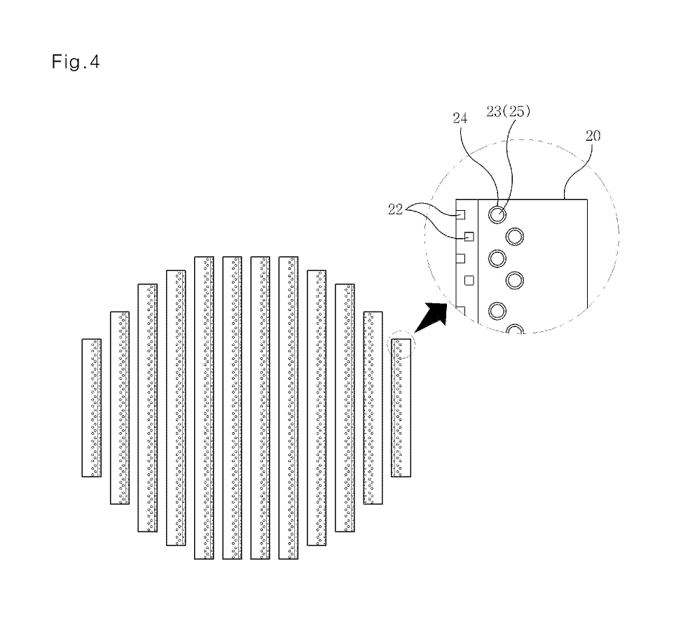

FIGS. 3 to 6 are views showing a method for manufacturing the probe card in accordance with the first embodiment of the present invention wherein FIG. 3 is a plan view of a supportable board; FIG. 4 is a plan view of a probe substrate; FIG. 5 is a plan view showing the supportable board and the probe substrate after a bonding step; and FIG. 6 is a plan view showing the supportable board and the probe substrate after a chip-size separation step.

As shown in FIG. 3, the supportable board 10 is a circular plate similar to a wafer and has a plurality of long openings 11 formed at regular intervals. As shown in FIG. 2, the openings 11 allow the connecting members 50 to travel therethrough so as to electrically connect the probe substrate 20 and the main circuit board 40. Alternatively, the supportable board 10 may be composed of a plurality of long blocks that form together a shape similar to the wafer.

As shown in FIG. 4, the probe substrate 20 is composed of a plurality of long blocks that form together a shape similar to the wafer. Each block of the probe substrate 20 has a circuit pattern (21 of FIG. 2) formed therein and pads 22 arranged along one edge of the surface thereof. Additionally, the probe substrate 20 has a plurality of via holes 23 each having a plated layer (24 of FIG. 2) formed on the inner wall thereof.

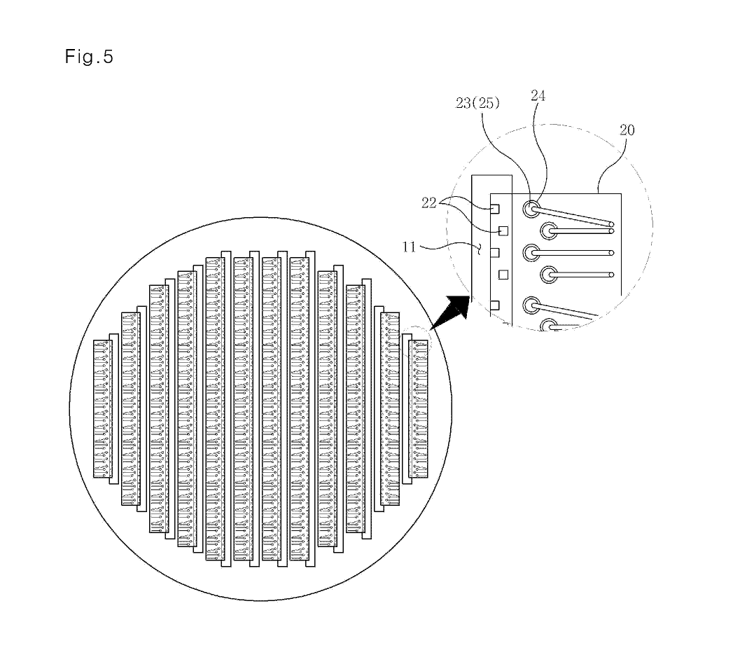

Instead of the long blocks in this embodiment, the probe substrate 20 may be made in the form of a circular plate as shown in FIG. 7. In this case, the probe substrate 20 has second through holes 26 corresponding to the openings 11 of the supportable board 10. Additionally, the pads 22 are arranged along one edge of each of the second through holes 26.

As shown in FIG. 5, the supportable board 10 shown in FIG. 3 and the probe substrate 20 shown in FIG. 4 are bonded to each other. At this time, each block of the probe substrate 20 is disposed in close proximity to each through hole 11 of the supportable board 10 such that one edge of each block of the probe substrate 20, on which the pads 22 are arranged, is overlaid on one edge of the through hole 11. As discussed above, a bonding of the probe substrate 20 and the supportable board 10 may use a nonconductive adhesive (12 of FIG. 2).

The probe pins 30 are simultaneously inserted into the via holes 23 of the probe substrate 20 by using a pin array frame disclosed in Korean Patent Application No. 2008-0028824. The probe pins 30 may be inserted into the via holes 23 before or after the probe substrate 20 and the supportable board 10 are bonded to each other. A simultaneous insertion of the probe pins 30 into the via holes 23 by means of the pin array frame may allow the probe pins 30 to be easily mounted on the probe substrate 20 and to be exactly arranged. FIG. 5 shows the probe pins 30 inserted into the respective via holes 23 of the probe substrate 20.

In case of the probe substrate 20 having a circular plate form as shown in FIG. 7, the supportable board 10 and the probe substrate 20 may be bonded to each other at once.

Thereafter, as shown in FIG. 6, the probe substrate 20 is separated into individual parts each having a given size. Namely, the probe substrate 20 is cut at intervals along the X axis of FIG. 1 and thereby divided into several parts in the Y-axis direction. A reference numeral 26 indicates a separation region of the probe substrate 20. This separation process may be performed using a laser cutting technique, a routing technique, or a wafer scribing technique, all of which are well known in the art.

A separation size of the probe substrate 20 may be determined in consideration of material, thermal expansion coefficient, etc. of the probe substrate 20. Namely, the probe substrate 20 is divided into individual parts each of which has a specific size that disallows a deviation in location of the probe pins 30 from the chip pads in spite of thermal expansion or contraction of the probe substrate 20. For example, a separation size of the probe substrate 20 may be identical to, smaller than, or larger than a chip size of the wafer. When the probe substrate 20 is separated into individual parts, a gap corresponding to the separation region 26 is created between adjacent separated parts of the probe substrate 20. Therefore, even though the probe substrate 20 increases in size due to thermal expansion, the gap 26 between the separated parts of the probe substrate 20 may absorb such an increase.

Preferably, the separation process may be completely performed for the probe substrate 20 and the adhesive under the probe substrate 20. Additionally, the separation process may be performed before or after the probe substrate 20 and the supportable board 10 are combined with the main circuit board 40.

Meanwhile, in case of the probe substrate 20 having a circular plate form as shown in FIG. 7, the probe substrate 20 may be separated in the Y-axis direction as well as the X-axis direction of FIG. 1.

After the probe substrate 20 and the supportable board 10 are combined with the main circuit board 40, the probe substrate 20 and the main circuit board 40 are electrically connected to each other using the connecting members (50 of FIG. 2) through the openings 11 of the supportable board 10. This connection process may use a wire bonding technique, an individual soldering technique, or the like, which are well known in the art.

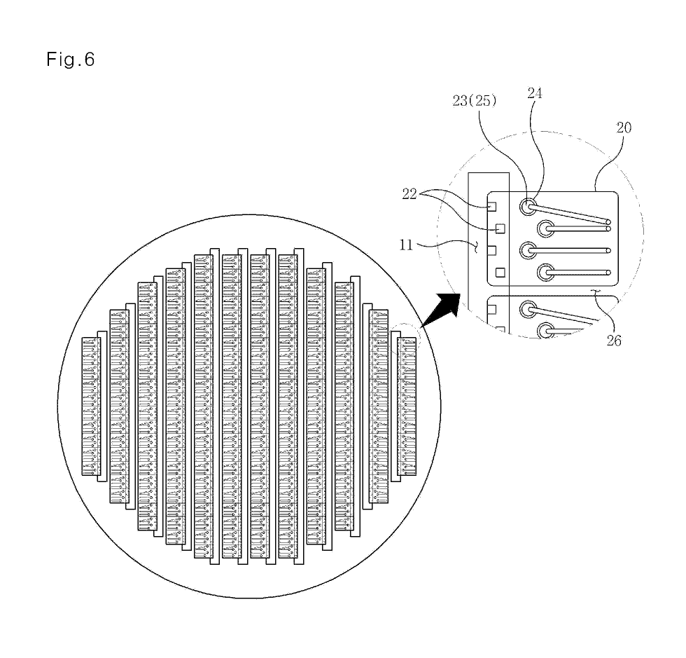

According to the second embodiment of the present invention, the probe substrate may include a first probe substrate and a second probe substrate. Hereinafter, the second embodiment will be described with reference to FIG. 8, which is a cross-sectional view partially showing a probe card in accordance with the second embodiment of the present invention. Herein, the repetition of the same as described above will be avoided.

As shown in FIG. 8, the probe card 200 includes the supportable board 10, the first probe substrate 20, the probe pins 30, the main circuit board 40, the connecting members 50, and the second probe substrate 60.

The first probe substrate 20 is identical to the probe substrate in the first embodiment except that the probe pins 30 are not inserted into the first probe substrate 20. In this embodiment, the second probe substrate 60 for receiving and fixing the probe pins 30 is added to the first probe substrate 20.

Contrary to the first probe substrate 20, the second probe substrate 60 is made of a material having a thermal expansion coefficient similar to the wafer, such as silicon, ceramic, glass, etc. namely, the material of the second probe substrate 60 is similar to that of the supportable board 10. Since the material of the second probe substrate 60 to which the probe pins 30 are fixed is similar to the wafer, the probe card 200 according to the second embodiment can favorably cope with thermal expansion or contraction of the wafer. Therefore, the first and second probe substrates 20 and 60 of the probe card 200 may not be separated.

However, any mechanical deformation such as a bending may occur in the second probe substrate 60 due to a difference in thermal expansion coefficient between the first and second probe substrates 20 and 60. Therefore, the first probe substrate 20 may be separated into individual parts having a specific size that disallows any mechanical deformation of the second probe substrate 60. For the above reason, the first probe substrate 20 may be separated into individual parts, and then the second probe substrate 60 may be bonded onto the separated first probe substrate 20. Alternatively, the first and second probe substrates 20 and 60 may be bonded to each other and then simultaneously separated together into individual parts.

In order to receive the probe pins 30, the second probe substrate 60 has a plurality of first via holes 61 and second via holes 62. The first via holes 61 are formed at the same positions as the via holes 23 of the first probe substrate 20, whereas the second via holes 62 are formed at positions different from the via holes 23. The second via holes 62 are electrically connected to some of the first via holes 61 through rerouting patterns 63. A plated layer is formed on the inner walls of the first and second via holes 61 and 62 of the second probe substrate 60.

Like the via holes 23 of the first probe substrate 20, the first and second via holes 61 and 62 of the second probe substrate 60 are filled with the conductive adhesive 25. The probe pins 30 are inserted into the first via holes 61 that are not connected to the rerouting patterns 63, or into the second via holes 62. As discussed above, the probe pins 30 may have a cantilever form or a vertical form or may be MEMS pins.

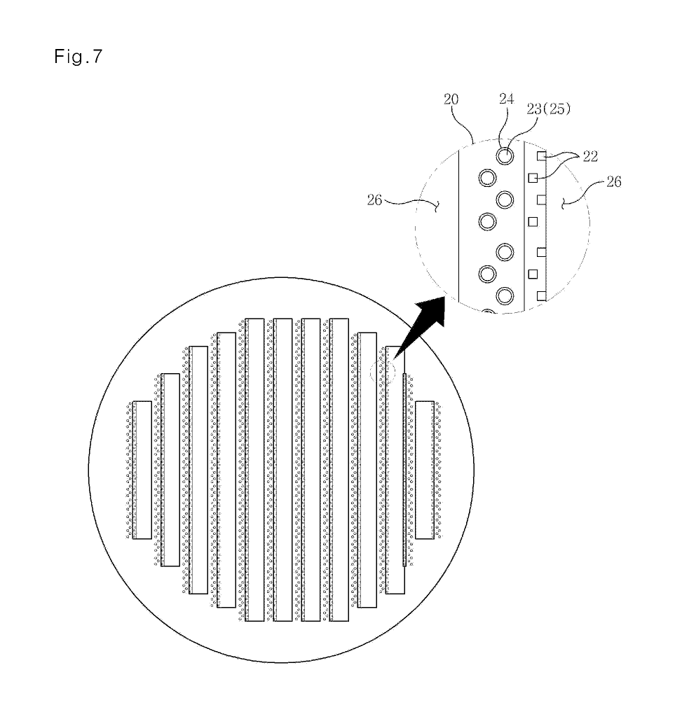

According to the third embodiment of the present invention, the connecting members for connecting the probe substrate and the main circuit board may pass through any holes formed in the main circuit board and then be connected to the lower surface of the main circuit board. Hereinafter, the third embodiment will be described with reference to FIG. 9, which is a cross-sectional view partially showing a probe card in accordance with the third embodiment of the present invention. Herein, the repetition of the same as described above will be avoided.

As shown in FIG. 9, the probe card 300 includes the supportable board 10, the first probe substrate 20, the probe pins 30, the main circuit board 40, and the connecting members 50. Furthermore, the probe card 300 includes an upper stiffener 70 formed between the main circuit board 40 and the supportable board 10, and a lower stiffener 80 formed on the lower surface of the main circuit board 40. In some cases, one or both of the upper and lower stiffeners 70 and 80 may be omitted. Additionally, the upper and lower stiffeners 70 and 80 are joined to the supportable board 10 and the main circuit board 40 through joining members such as screws 90.

Particularly, the main circuit board 40 in this embodiment has through holes 41 corresponding to the openings 11 of the supportable board 10. Therefore, each connecting member 50 connected at one end thereof to the probe substrate 20 may pass both the through hole 11 of the supportable board 10 and the through hole 41 of the main circuit board 40 and then be connected at the other end thereof to the lower surface of the main circuit board 40. A connection between the connecting members 50 and the main circuit board 40 may use a soldering technique as described above. By connecting the connecting members 50 to the lower surface of the main circuit board 40, connection spots between the connecting members 50 and the main circuit board 40 may not be located in the openings 11. It is therefore possible to reduce the size of the openings 11 or to effectively utilize the openings 11. Furthermore, this may be favorable in view of process.

Additionally, since the connecting members 50 connected to the lower surface of the main circuit board 40 are fixed by the lower stiffener 80, the connection reliability of the connecting members 50 may be improved. If the lower stiffener 80 is not used, any additional guide frame (not shown) may be placed on sidewalls of the through holes 41 of the main circuit board 40 to enhance the connection reliability of the connecting members 50.

Besides, this embodiment shown in FIG. 9 suggests any other modifications. One of them is the arrangement of the probe pins 30. While the probe pins 30 are arranged in one direction in the embodiments respectively shown in FIGS. 2 and 8, the probe pins 30 of this embodiment shown in FIG. 9 are disposed in the form of pairs facing each other. Like this, the probe pins 30 in the probe card of this invention may be arranged in various forms.

Additionally, while the connecting members 50 are extended from one side of the probe substrate 20 into the openings 11 in the embodiments respectively shown in FIGS. 2 and 8, the connecting members 50 of this embodiment shown in FIG. 9 are extended from both sides of the probe substrate 20 into the openings 11.

Like the second embodiment in FIG. 8, this embodiment shown in FIG. 9 may be favorably applied to the probe card including the first and second probe substrates.

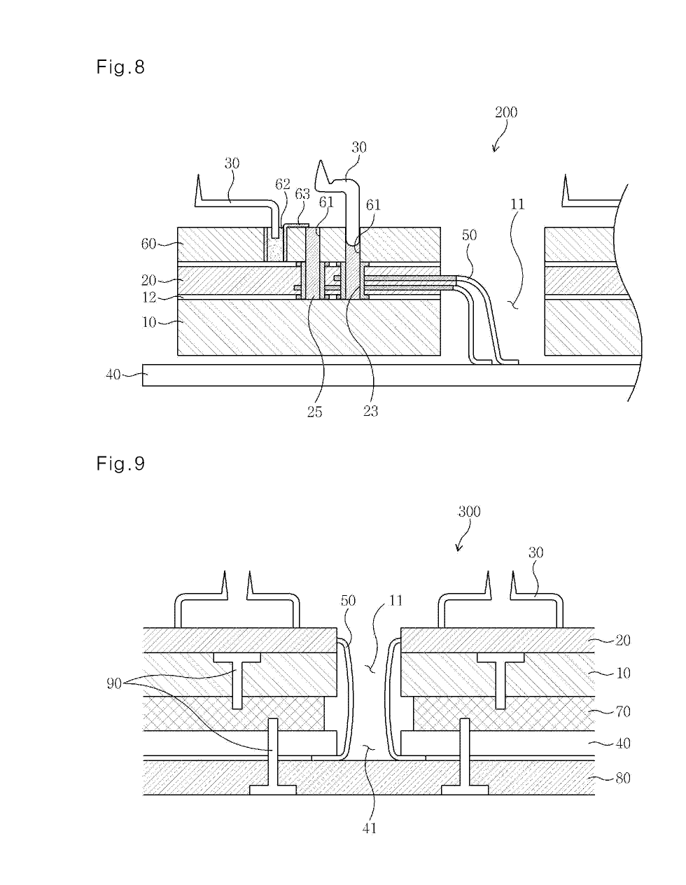

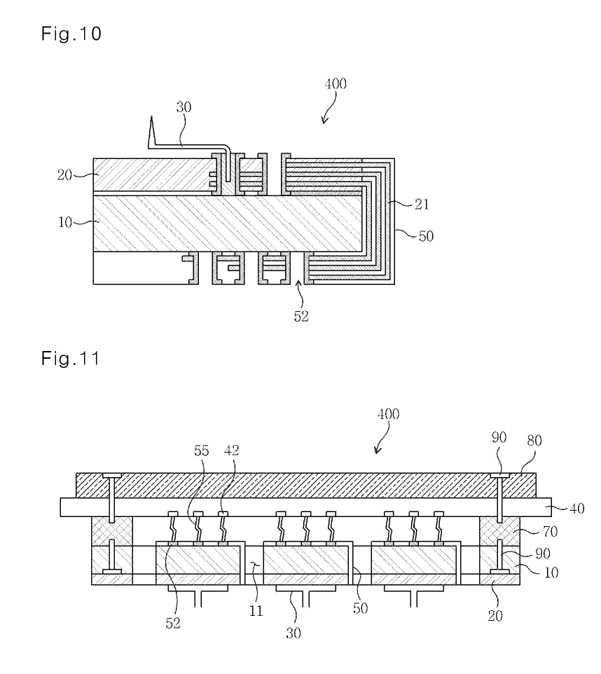

According to the fourth embodiment of the present invention, the connecting members may not be directly connected to the main circuit board but indirectly connected through additional second connecting members. Hereinafter, the fourth embodiment will be described with reference to FIGS. 10 and 11. FIG. 10 is a cross-sectional view partially showing a probe card in accordance with the fourth embodiment of the present invention, and FIG. 11 is a cross-sectional view showing the probe card in accordance with the fourth embodiment of the present invention. Herein, the repetition of the same as described above will be avoided.

As shown in FIGS. 10 and 11, the probe card 400 includes the supportable board 10, the probe substrate 20, the probe pins 30, the main circuit board 40, the connecting member 50, the upper and lower stiffeners 70 and 80, and joining members 90. Particularly, the probe card 400 according to this embodiment further includes second connecting members 55, which may also be referred to as intermediate connectors.

The connecting member 50 may be an FPCB in which microstrips or striplines are organized by the multi-level circuit patterns 21 with insulating layers interposed. Particularly, a rigid section of an RFPCB may form the probe substrate 20, and a flexible section of the RFPCB may form the connecting member 50. The connecting member 50 is extended to the lower surface of the supportable board 10 along the lateral side of the supportable board 10. Then the connecting member 50 is bonded to the supportable board 10 through a nonconductive adhesive such as epoxy.

A portion of the connecting member 50 extended onto the lower surface of the supportable board 10 has connection pads 52 for electrical connections. These connection pads 52 may be formed of via holes having plated layers or filled with conductive material. The second connecting members 55 are respectively attached to the connection pads 52 of the connecting member 50, so the connecting member 50 is electrically connected to the main circuit board 40 through the second connecting members 55. Like the connecting member 50, the main circuit board 40 has connection pads 42 to be attached to the second connecting members 55.

The second connecting members 55 may use various conductive elastic means well known in the art. For example, any elastic means offering an electrical path, such as pogo pins, springs in various forms, conductive elastomer, or the like, may be used as the second connecting members 55. Additionally, the second connecting members 55 may be bonded to the connection pads 52 and 42 by using various well-known techniques such as a mechanical contact technique, a mechanical insertion technique, a soldering technique, etc.

Using the connecting member 50 extended to the lower surface of the supportable board 10 may make it possible to reduce the size of the openings 11 of the supportable board 10 or to effectively utilize the openings 11, like the above-discussed third embodiment. This may also be favorable in view of process. Additionally, even though the connecting member 50 extended to the lower surface of the supportable board 10 fails to meet the flatness with the main circuit board 40, the elasticity of the second connecting members 55 may compensate for inconsistency in flatness between the connecting member 50 and the main circuit board 40 and also maintain the connection reliability.

Like the second embodiment in FIG. 8, the fourth embodiment may be favorably applied to the probe card including the first and second probe substrates.

While this invention has been particularly shown and described with reference to an exemplary embodiment thereof, it will be understood by those skilled in the art that various changes in form and details may be made therein without departing from the spirit and scope of the invention as defined by the appended claims.

1. A probe card comprising:
a main circuit board;
a supportable board combined with the main circuit board and made of a material having a thermal expansion coefficient similar to that of a wafer;
a probe substrate bonded onto the supportable board, including a circuit pattern formed therein and electrically connected to the main circuit board, and further including a plurality of via holes electrically connected to the circuit pattern;
a conductive adhesive filled in the via holes; and
probe pins respectively inserted into the via holes, mechanically fixed to the via holes through the conductive adhesive, and electrically connected to the circuit pattern,
wherein the probe substrate is separated into individual parts having a specific size that disallows a deviation in location of the probe pins from chip pads of the wafer in spite of thermal expansion or contraction of the probe substrate.

2. The probe card of claim 1, wherein the probe substrate before being separated has the shape of a circular plate resembling the wafer or is composed of a plurality of long blocks forming together a resultant shape resembling the wafer.

3. The probe card of claim 1, further comprising:
connecting members electrically connecting the probe substrate and the main circuit board through at least one opening formed in the supportable board.

4. The probe card of claim 3, wherein the main circuit board includes a through hole corresponding to the opening, and wherein each of the connecting members is connected at one end thereof to the probe substrate, passes through the opening and the through hole, and is connected at the other end thereof to a lower surface of the main circuit board.

5. The probe card of claim 3, wherein the connecting members are extended to a lower surface of the supportable board along a lateral side of the supportable board.

6. The probe card of claim 5, further comprising:
second connecting members electrically connecting the main circuit board to the connecting members extended to the lower surface of the supportable board.

7. A probe card comprising:
a main circuit board;
a supportable board combined with the main circuit board and made of a material having a thermal expansion coefficient similar to that of a wafer;
a first probe substrate bonded onto the supportable board, including a circuit pattern formed therein and electrically connected to the main circuit board, and further including a plurality of via holes electrically connected to the circuit pattern and filled with a conductive adhesive;
a second probe substrate bonded onto the first probe substrate, made of a material having a thermal expansion coefficient similar to that of the wafer, including first via holes formed at the same positions as the via holes of the first probe substrate, and further including second via holes formed at positions different from the via holes of the first probe substrate and electrically connected to some of the first via holes; and
probe pins respectively inserted into the first via holes not connected to the second via holes and into the second via holes, mechanically fixed to the inserted via holes through the conductive adhesive, and electrically connected to the circuit pattern.

8. The probe card of claim 7, wherein the first probe substrate is separated into individual parts having a specific size that disallows mechanical deformation of the second probe substrate in spite of a difference in thermal expansion coefficient between the first and second probe substrates.

9. The probe card of claim 7, wherein each of the first and second probe substrates has the shape of a circular plate resembling the wafer or is composed of a plurality of long blocks forming together a resultant shape resembling the wafer.

10. The probe card of claim 7, further comprising:
connecting members electrically connecting the first probe substrate and the main circuit board through at least one opening formed in the supportable board.

11. The probe card of claim 10, wherein the main circuit board includes a through hole corresponding to the opening, and wherein each of the connecting members is connected at one end thereof to the first probe substrate, passes through the opening and the through hole, and is connected at the other end thereof to a lower surface of the main circuit board.

12. The probe card of claim 10, wherein the connecting members are extended to a lower surface of the supportable board along a lateral side of the supportable board.

13. The probe card of claim 12, further comprising:
second connecting members electrically connecting the main circuit board to the connecting members extended to the lower surface of the supportable board.

14. A method for manufacturing a probe card, the method comprising steps of:
preparing a supportable board made of a material having a thermal expansion coefficient similar to that of a wafer;
preparing a probe substrate including a plurality of via holes filled with a conductive adhesive and electrically connected to a circuit pattern formed therein;
inserting probe pins into the via holes of the probe substrate and then bonding the probe substrate onto the supportable board;
separating the probe substrate into individual parts having a specific size that disallows a deviation in location of the probe pins from chip pads of the wafer in spite of thermal expansion or contraction of the probe substrate; and
combining the supportable board with a main circuit board and then electrically connecting the probe substrate to the main circuit board.

15. The method of claim 14, wherein the step of bonding the probe substrate onto the supportable board uses the probe substrate having the shape of a circular plate resembling the wafer or the probe substrate composed of a plurality of long blocks forming together a resultant shape resembling the wafer.

16. The method of claim 14, wherein the step of inserting the probe pins into the via holes of the probe substrate includes simultaneously inserting the probe pins using a pin array frame.

17. The method of claim 14, wherein the step of inserting the probe pins is performed before or after the step of bonding the probe substrate onto the supportable board.

18. The method of claim 14, wherein the supportable board includes at least one opening, and wherein the step of electrically connecting the probe substrate to the main circuit board uses connecting members passing through the opening.

19. The method of claim 18, wherein the main circuit board includes a through hole corresponding to the opening, and wherein each of the connecting members is connected at one end thereof to the probe substrate, passes through the opening and the through hole, and is connected at the other end thereof to a lower surface of the main circuit board.

20. The method of claim 18, wherein the connecting members are extended to a lower surface of the supportable board along a lateral side of the supportable board and electrically connected to the main circuit board through second connecting members.

21. A method for manufacturing a probe card, the method comprising steps of:
preparing a supportable board made of a material having a thermal expansion coefficient similar to that of a wafer;
preparing a first probe substrate including a plurality of via holes filled with a conductive adhesive and electrically connected to a circuit pattern formed therein;
preparing a second probe substrate made of a material having a thermal expansion coefficient similar to that of the wafer, including first via holes formed at the same positions as the via holes of the first probe substrate and filled with the conductive adhesive, and further including second via holes formed at positions different from the via holes of the first probe substrate, electrically connected to some of the first via holes, and filled with the conductive adhesive;
inserting probe pins into the first via holes not connected to the second via holes and into the second via holes and then bonding the supportable board, the first probe substrate and the second probe substrate; and
combining the supportable board with a main circuit board and then electrically connecting the first probe substrate to the main circuit board.

22. The method of claim 21, further comprising a step of:
separating the first probe substrate into individual parts having a specific size that disallows mechanical deformation of the second probe substrate in spite of a difference in thermal expansion coefficient between the first and second probe substrates.

23. The method of claim 21, wherein the step of bonding the supportable board, the first probe substrate and the second probe substrate uses the first and second probe substrates each having the shape of a circular plate resembling the wafer or composed of a plurality of long blocks forming together a resultant shape resembling the wafer.

24. The method of claim 21, wherein the step of inserting the probe pins into the first and second via holes of the second probe substrate includes simultaneously inserting the probe pins using a pin array frame.

25. The method of claim 21, wherein the step of inserting the probe pins is performed before or after the step of bonding the supportable board and the first and second probe substrates.

26. The method of claim 21, wherein the supportable board includes at least one opening, and wherein the step of electrically connecting the first probe substrate to the main circuit board uses connecting members passing through the opening.

27. The method of claim 26, wherein the main circuit board includes a through hole corresponding to the opening, and wherein each of the connecting members is connected at one end thereof to the first probe substrate, passes through the opening and the through hole, and is connected at the other end thereof to a lower surface of the main circuit board.

28. The method of claim 26, wherein the connecting members are extended to a lower surface of the supportable board along a lateral side of the supportable board and electrically connected to the main circuit board through second connecting members.
